(19) United States
(12) Patent Application Publication
(10) Pub. No.: US 2007/0079866 A1
(43) Pub. Date: Apr. 12, 2007

(54) System and method for making an improved thin film solar cell interconnect

(75) Inventors: Peter G. Borden, San Mateo, CA (US); David J. Eaglesham, Livermore, CA (US)

Correspondence Address: Applied Materials, Inc., P.O. Box 450A, Santa Clara, CA, 95052, US

(73) Assignee: Applied Materials, Inc.

(21) Appl. No.: 11/245,620

(22) Filed: Oct. 7, 2005

(51) Int. Cl. H02N 6/00; H01L 31/00

(52) U.S. Cl. 136/252; 136/244

(57) ABSTRACT

In a module of photovoltaic cells, a method of forming the module interconnects includes a single cutting process after the deposition of all active layers. This simplifies the overall process to a set of vacuum steps followed by a set of interconnect steps, and may significantly module quality and yield. According to another aspect, an interconnect forming method includes self-aligned deposition of an insulator. This simplifies the process because no alignment is required. According to another aspect, an interconnect forming method includes a scribing process that results in a much narrower interconnect which may significantly boost cell efficiency, and allow for narrower cell sizes. According to another aspect, an interconnect includes an insulator layer that greatly reduces shunt current through the active layer, which can greatly improve cell efficiency.

### FIELD OF THE INVENTION

The present invention relates generally to photovoltaic devices, and more particularly to a system and method for making improved interconnects in thin-film photovoltaic devices.

### BACKGROUND OF THE INVENTION

Thin film solar modules offer an attractive way to achieve low manufacturing cost with reasonable efficiency. These modules are made from a variety of materials, including amorphous silicon, amorphous silicon germanium, copper indium gallium selenide (CIGS), and cadmium telluride. A common feature of these solar modules is the deposition on a large area insulator such as a glass sheet.

Another common feature of these modules is the use of scribes and interconnects to divide the large area deposited layer into a number of cells and/or sub-cells. A top view of a typical module divided in this fashion is shown in FIG. 1. As shown in FIG. 1, a module 100 is divided into a plurality of cells 102 (i.e. stripes) that are series connected (e.g. electrically connected together in a horizontal direction in this drawing) via interconnects 104. The interconnects are formed in the module using scribes and conductors as will be explained in more detail below. However, it should be noted here that the length L of such modules 100 can be 1 meter or more. Meanwhile, the width of the interconnects, which typically run almost the entire length L of the module, are typically around 700-1000 μm, and the width of the cells (i.e. stripes) are typically about 1 cm. As will be understood by those of skill in the art, FIG. 1 is a simplified drawing of a typical module, and the module can further include other passive and active components not shown in FIG. 1 such as electrodes and terminals.

The division of the module into cells is done for several reasons, the principal ones being that the resulting series interconnection provides a high voltage output (equal to the sum of the voltages of the individual cells) with reduced current (equal to the current of a single cell), and that the lower current diminishes the effect of the series of the relatively high resistance transparent conductors used in such cells. More particularly, by Ohm's law, P=IV=I²R (P=power dissipated in resistance R through which current I flows), so a reduction in current quadratically reduces the power loss in the series resistance.

An example of a conventional interconnect process flow is shown in FIGS. 2A-F. This flow is for a module made from a material such as CIGS, and FIGS. 2A-F could illustrate the process flow for a greatly enlarged portion 106 of FIG. 1 from the perspective of a cross-sectional side view of FIG. 1 taken across one of the interconnects 104.

In the first step shown in FIG. 2A, a conducting metal 202 such as molybdenum is deposited on a substrate such as glass 204 using a vacuum sputtering system. In the second step shown in FIG. 2B, the metal 202 is laser scribed in a linear cut 206 across the module (as mentioned above, this cut might be >1 meter in length). As shown in FIG. 2C, a CIGS semiconductor layer 208 is then deposited. As shown in FIG. 2D, a second scribe 210 parallel to the first isolates the CIGS layer into individual cells. As shown in FIG. 2E, a transparent conductive oxide (TCO) 212 is then deposited; in one example the TCO is comprised of ZnO. Finally, as shown in FIG. 2F, a third scribe 214 is made to form the series connection 216, in which the ZnO from the deposition of layer 212 connects the top of one cell 218 to the bottom of the next cell 220.

In other cell designs, such as those using amorphous silicon, the layers are deposited in reverse order. One example of a conventional process for such designs is shown in FIGS. 3A-F. Generally, the process uses the same number of scribes, but the deposition order of the TCO and metal are reversed. Specifically, in FIG. 3A, a TCO layer 302 is first deposited on glass 304. Next, in FIG. 3B, the TCO layer 302 is laser scribed in a linear cut 306 across the module (as mentioned above, this cut might be >1 meter in length). As shown in FIG. 3C, a semiconductor layer 308 (e.g. amorphous silicon) is then deposited. As shown in FIG. 3D, a second scribe 310 parallel to the first scribe 306 isolates the semiconductor layer into individual cells. As shown in FIG. 3E, a metal layer 312 such as aluminum is then deposited to form a back contact. Finally, as shown in FIG. 3F, a third scribe 314 is made in the metal layer 312 which forms a series connection 316 in which the A1 from layer 312 connects one cell 318 to the next cell 320.

The conventional process flows in FIGS. 2 and 3 are shown schematically in FIG. 4. As shown in FIG. 4, there are three vacuum depositions 402, 406, 410, each respectively followed by a scribe step 404, 408 and 412. The conventional processes and the resulting modules such as those described above have a number of shortcomings. See generally, K. Brecl et al., “A Detailed Study of Monolithic Contacts and Electrical Losses in a Large-area Thin-film Module,” Prog. Photovolt. Res. Appl., Vol. 13, pp. 297-310 (2005).

With reference to FIG. 3F, the width W of the module interconnects resulting from the process is fairly large-up to 1 mm. This forces use of wider cells to maintain acceptable active area ratios and, to minimize resistive losses in the TCO, thicker TCO layers. This increases optical transmission loss through the TCO, causing a loss of about 10% of the module efficiency. Some attempts have been made to reduce the width of such interconnects, such as the method disclosed in T. M. Walsh et al., “Novel Method for the Interconnection of Thin-Film Silicon Solar Cells on Glass,” Conference Record of the Thirty-first IEEE Photovoltaic Specialists Conference, 3-7 Jan. 2005, pp. 1229-32. However, such attempts have been unsatisfactory because, for example, (1) they rely on multiple scribes that must be aligned to one another (which is difficult due to registration errors in the scribes over a long distance) and (2) they do not suppress the parasitic resistance, as will be described below.

Another problem with the module interconnects is that they contain a parasitic reverse resistor through the active layer of the semiconductor that can significantly degrade cell performance. More particularly, as shown in FIG. 5, this parasitic resistance allows a shunt current 502 to flow back through the active layer, degrading the flow of the main current 504 through the interconnect. This forces use of a wide scribe line to increase the length—and therefore the resistance—of this parasitic circuit element (and hence, decrease the shunt current). The wider scribe lines further lead to the need for wider cells as discussed above.

As for the conventional process flows themselves, the three different scribe steps are dirty processes, leaving residues and particles. This can cause damage near the edge of the scribe, further decreasing efficiency of the resulting module. Moreover, the multiple transitions between vacuum and air cause further contamination in the resulting module, and increase expense of the overall process because of the need for multiple load locks. Still further, the air exposure in the middle of the deposition of active layers can degrade performance of the resulting module.

Although very different from thin-film solar cell modules and their processing techniques, other types of solar cells can use separate processes for deposition of layers and forming interconnects between cells. For example, U.S. Pat. No. 4,278,473 teaches successively forming epitaxial layers comprising base and top regions of a solar cell on a semi-insulating GaAs substrate, and then forming interconnects between cells using IC fabrication steps including lithography with masks. However, such techniques involving IC fabrication and lithography with masks are not practical for thin-film modules which are typically much greater than 10 cm on a side. Moreover, such techniques are not readily extendable to thin-film solar cells because GaAs solar cells have no metal contact layers (e.g. layers corresponding to 202 and 212 in FIG. 2 or 302 and 312 in FIG. 3).

Therefore, it would desirable to overcome many of the shortcomings of the conventional ways of forming interconnects in a thin-film photovoltaic device. The present invention aims at doing this, among other things.

### SUMMARY OF THE INVENTION

The present invention provides a system and method of forming interconnects in a photovoltaic module.

According to one aspect, a method according to the invention includes forming the module interconnect with a single cutting process after the deposition of all active layers. This simplifies the overall process to a set of vacuum steps followed by a set of interconnect steps, and may significantly improve module quality and yield.

According to another aspect, a method according to the invention includes self-aligned deposition of an insulator. This simplifies the process because no alignment is required, and reduces the area used for interconnect, because no width is required to take up alignment errors.

According to another aspect, a method according to the invention includes a scribing process that results in a much narrower interconnect which may significantly boost module efficiency, and allow for narrower cell sizes.

According to another aspect, an interconnect according to the invention includes an insulator layer that greatly reduces shunt current through the active layer, which can greatly improve module efficiency.

In some embodiments of the invention, a method for forming an interconnect for a thin film solar cell comprises depositing a stack of active and conducting layers of the cell, wherein the depositing step is done in a single process sequence, and forming the interconnect.

In other embodiments of the invention, a system for forming an interconnect for a thin film solar cell comprises a scriber and a deposition system, wherein the deposition system deposits a stack of active and conducting layers of the cell in a single vacuum process.

In still further embodiments of the invention, in a module of thin-film solar cells, at least one the cells comprises a stack on a substrate comprising at least an active layer and a top conducting layer, the cell having a wall abutting all layers of the stack and extending to a surface of the substrate, and an interconnect to an adjacent one of the cells, the interconnect including a conductive ledge on the surface of the substrate that connects to the adjacent cell and is disposed across from the wall along the substrate by a gap, and a conductor bridging the gap that forms an electrical connection between the top conducting layer and the conductive ledge. According to alternative embodiments of the invention, a method for forming an interconnect for a thin film solar cell includes depositing an active layer on a bottom conducting layer of the cell and making a cut through the layers using a shaped laser beam such that a first portion of the cut proceeds through the bottom conducting layer while a second portion of the cut does not but exposes a conducting ledge coupled to an adjacent cell.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a top view of a conventional module of thin film photovoltaic cells separated by interconnects;

FIGS. 2A-F show a conventional process of forming an interconnect between thin film photovoltaic cells;

FIGS. 3A-F show a conventional process of forming an interconnect between thin film photovoltaic cells;

FIG. 4 is a block diagram of a conventional process flow;

FIG. 5 illustrates the problem of shunt current in a module having an interconnect formed by conventional processes;

FIGS. 6A-E show a method of forming an interconnect in accordance with an embodiment of the invention;

FIG. 7 illustrates an alternative method of forming interconnects in accordance with the invention;

FIG. 8 is a block diagram illustrating an overall process flow according to the invention;

FIG. 9 is a block diagram of a factory for making photovoltaic modules in accordance with the invention;

FIG. 10 illustrates the reduction of shunt current made possible by the interconnect forming method of the present invention;

FIGS. 11A-F show a method of forming an interconnect in accordance with a first alternative embodiment of the invention; and

FIGS. 12A-C show a method of forming an interconnect in accordance with a second alternative embodiment of the invention.

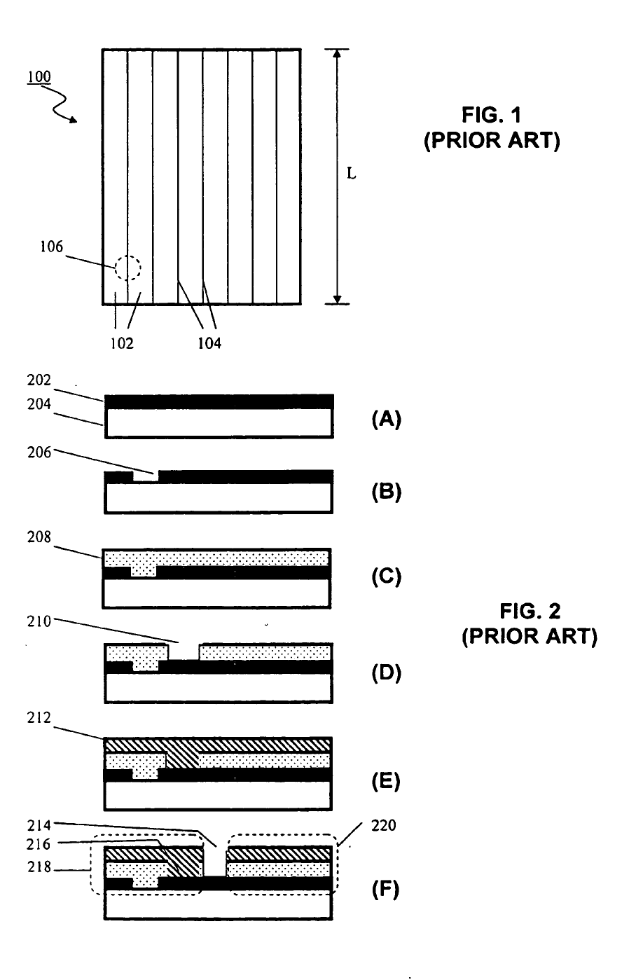

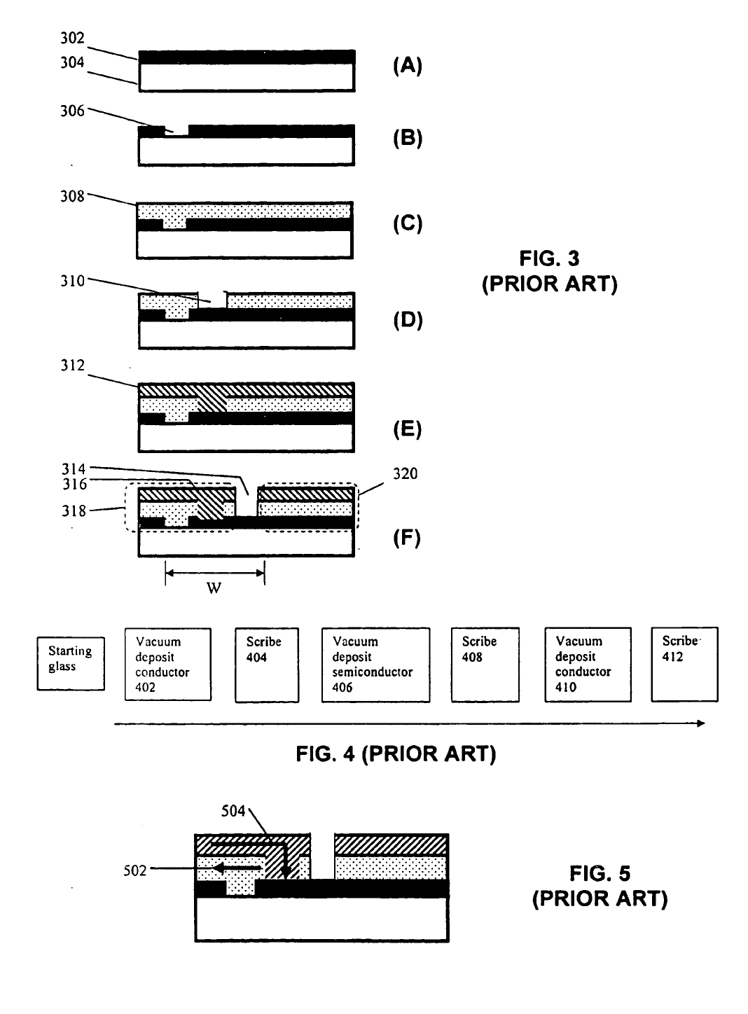

### DESCRIPTION OF REFERENCE NUMERALS ON THE DRAWINGS

The following describes the reference numerals used on the drawings. This description is intended to be illustrative rather than limiting and those skilled in the art will appreciate that various substitutions and modifications can be made while remaining within the scope of the invention:
100 module
102 cell
104 interconnect
202 conductor
204 substrate
206 first scribe
208 semiconductor
210 second scribe
212 TCO
214 third scribe
216 series connection
218 first cell
220 next cell
302 TCO
304 glass substrate
306 first scribe
308 amorphous silicon
310 second scribe
312 metal
314 third scribe
316 series connection
318 first cell
320 next cell
402 first vacuum deposition
404 first scribe
406 second vacuum deposition
408 second scribe
410 third vacuum deposition
412 third scribe
502 shunt current
504 main current
602 metal
604 semiconductor
606 TCO
608 substrate
610 first scribe
612 second scribe
614 conducting ledge
616 insulator
618 conductor
620 first cell
622 next cell
802 vacuum deposition
804 scribe and connect process
900 factory
902 deposition system
904 scribe and connect system
906 chamber
908 linear track
1004 shunt current
1102 metal
1104 substrate
1106 first scribe
1108 semiconductor
1110 conducting ledge
1112 second scribe
1114 isolating groove
1116 top conductor
1118 third scribe
1202 metal
1204 substrate
1206 first scribe
1208 semiconductor
1210 conducting ledge
1212 second scribe
1214 isolating groove
1216 re-entrant sidewall
1218 top conductor

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

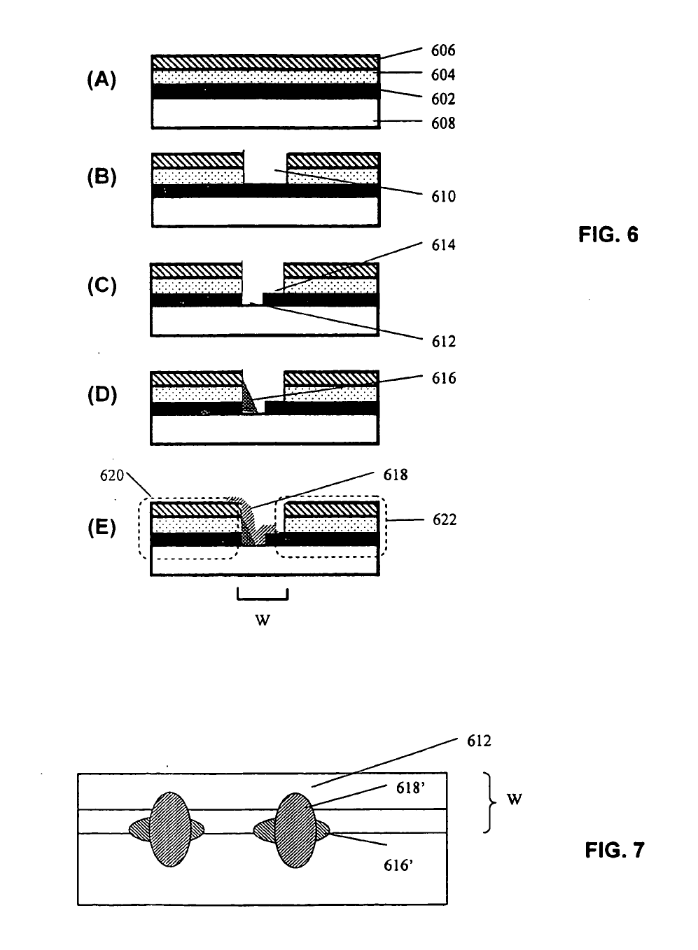

FIGS. 6A-E show an improved process sequence resulting in an improved thin-film photovoltaic device in accordance with an embodiment of the invention.

In the first step shown in FIG. 6A, the entire conductor and semiconductor stack 602-606 is deposited on the substrate 608, which in some embodiments may be an insulator such as glass, and in other embodiments may be a metal foil with a deposited insulator. In one embodiment, layer 602 is a metal such as molybdenum or a TCO such as ZnO, layer 604 is a semiconductor such as CIGS, layer 606 is a TCO such as ZnO. In some embodiments, the entire stack is about 2-3 μm thick. In other embodiments, a very thin layer of a metal such as palladium is further deposited on top of the stack. This layer can be only a few angstroms thick, such that it is substantially transparent, yet still thick enough to assist contacting the top layer to the interconnect, as will be described below. It should be noted that there may be additional layers in the stack, such as between the CIGS layer and the TCO layer for improved electrical performance of the photovoltaic cell stack, (e.g. an intermediate CdS layer forms a heterojunction for carrier confinement and an iZnO layer provides a higher resistance layer that reduces the effect of defects in the CIGS) and those skilled in the art will appreciate the various alternatives that can be made after being taught by the present disclosure.

The stack deposition may be done in a single vacuum deposition system, such as a cluster tool or in-line coater. Since all of the three or more layers in the stack are sequentially deposited by the system without any intervening scribe steps as is conventionally done, only one load lock transition of the system is required. It should be noted that additional process steps such as thermal or lamp annealing may also be done within the vacuum system, and such steps may be done in controlled ambients or at different pressures, as a vacuum system typically includes gate valves to isolate individual chambers.

In the next step shown in FIG. 6B, a scribe 610 is made to the bottom conductor 602. As shown in FIG. 6C, a second scribe 612 is made using a smaller cut to create an exposed conductive ledge 614. Both of these scribes 610 and 612 may be made using a laser or mechanical scribe, or a combination of both. In an alternate embodiment, the two scribes are made at the same time.

In one embodiment where the scribes are made at the same time, a laser beam is used that has a skewed intensity profile, in that it is more intense on the left side than the right (with respect to the orientation of the drawing). This causes the left side to cut deeper than the right, forming the ledge 614. In another embodiment, two laser sources are coupled into a single fiber. One is an infrared source such as Nd:YAG with a wavelength of 1064 nm, for example, that penetrates the stack because its photon energy is below the bandgap of the semiconductor. This preferentially cuts through the conductor 602. The second is a shorter wavelength source, for example doubled Nd:YAG and 532 nm that cuts through the semiconductor 604 (e.g. CIGS) but not conductor 602. The width of the second cut is on the order of 20 to 50 μm. Some examples of possible laser technologies for various thin film materials that can be used in this step of the invention are described in I. Matulionis et al., “Wavelength and Pulse Duration Effects in Laser Scribing of Thin Films,” Conference Record of the Twenty-Sixth IEEE Photovoltaic Specialists Conference, 29 Sep.-3 Oct. 1997, pp. 491-494.

In other embodiments, one laser is shone on the sample from above and another from below. The beam from above is wider than the beam from below to form the ledge 614. In another embodiment, a mechanical scribe is used to cut the active layers 604 and 606 from the top and a laser is used to cut the conductor 602 from underneath, shining through the glass 608.

As shown in FIG. 6D, following the scribes, an insulator 616 is deposited on one wall. In the preferred embodiment, the insulator 616 is deposited using the following self-alignment method. A photosensitive polymer such as a polyimide or photoresist is applied over the entire module using any of a number of well-known methods, such an ink-jet, a spray or roller. Some possibly suitable polyimides that can be used are PIMEL® polyimides from AZ Electronic Materials. The polymer is exposed from the back side through the glass. This performs a self-aligned exposure within the groove (i.e. the conductor layer 602 blocks exposure of all the photoresist except the portion in the groove). Next the polymer is developed, leaving only a coating on the left wall (with respect to the orientation shown in the drawing) that was exposed through the groove. In another embodiment, the deposition is performed using an ink jet. In some cases this is not self-aligned. If, however, the ink-jet head is fixtured with respect to a laser beam, then the ink-jet can be self-aligned to the cut. For example, a fixture can hold both a fiber and an ink-jet, so that the ink-jet maintains a constant spatial relation to the laser beam emitting from the fiber.

Finally, as shown in FIG. 6E, a conductor 618 is deposited over the insulator 616 to connect the top of the left cell 620 to the bottom of right cell 622. This provides a series connection between the cells 620 and 622. The conductor 618 may be deposited by any of a number of means. In one method, the photosensitive polymer used in the insulator deposition process described above is coated with a thin conductive layer of a conductor such as Ni or Pd by, for example, electroless deposition. After exposure and development, this leaves a conductive surface that may be plated using, for example, electroless deposition. In another embodiment, after the polymer is developed the surface is coated with a thin substantially transparent (e.g., 50-100 Å thick) photoconductor such as CdS or ZnS using, for example, electroless deposition. Light is then shone through the back while a thicker conductor is plated on the surface. Plating occurs where the photoconductor base is conductive, thereby forming a thicker metal strap over the insulator. The excess photoconductor can be optionally etched off. In another embodiment, the polymer is tacky after patterning, and the surface is sprayed with a fine metal dust, such as Ni or Cu. This leaves a conductive deposit stuck to the patterned polymer that forms the base for electroless deposition. In some cases, the TCO layer 608 has been coated with a thin conductor that will not accept the electroless coating, but improves contact resistance to the plated conductor. In another embodiment, a catalyst such as RuO₄ is deposited on the insulator 616 using an ink-jet and an electroless coating is applied.

In any of these deposition methods, the entire length of the cut (e.g. the length L of the cut in the module) can be coated with insulator and conductor materials to form the interconnects. In another embodiment, only certain portions are coated. For example, as shown in FIG. 7, which can be considered a top view of the stack shown in FIG. 6E (with the direction L of the module running horizontally in the drawing), the insulator 616′ portions are deposited in discrete shapes elongated parallel to the axis of the cut and the conductor portions 618′ are deposited on the insulator portions 616′ in shapes elongated perpendicular to the cut. In one example, these shapes are about 20×50 μm and separated by about 200 μm.

One of the benefits of this invention is process simplification. As described above, the conventional process uses three cycles of a vacuum deposition followed by a scribe at air pressure. Therefore, the substrate must be brought into vacuum and back to air pressure three times. This adds cost to the process and creates the potential for contamination, both from the vacuum/vent cycles and from the exposure to atmosphere before the active layer is fully deposited. For example, the first conductor layer may acquire a residue from air exposure before the semiconductor is deposited. In addition, the scribe is a dirty process that leaves particulates and residues, which may therefore cause defects in the active layer.

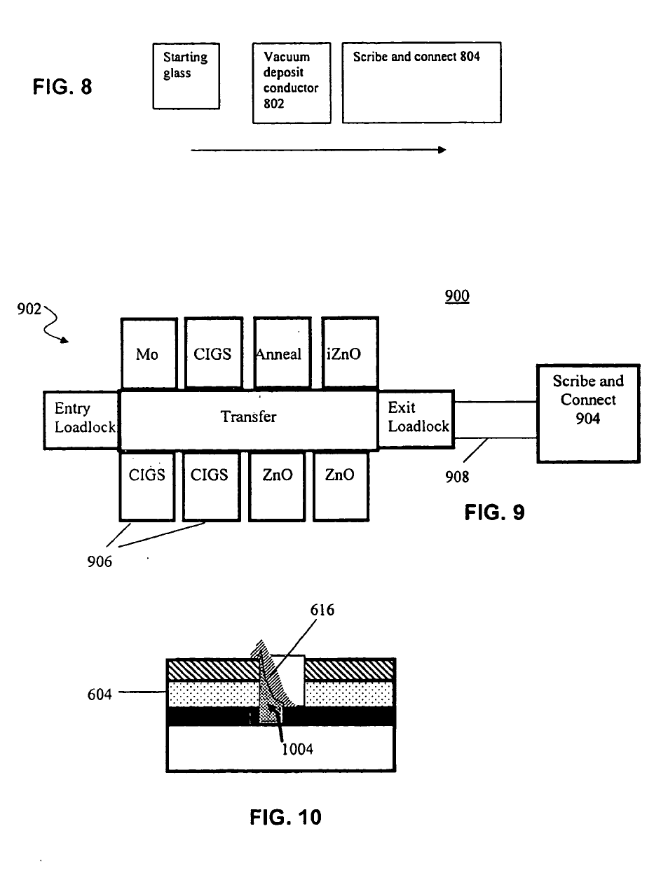

With this invention, as shown in FIG. 8, the entire active layer is deposited in a single vacuum process 802, and there is only one transition from air to vacuum to air. Furthermore, the cut is performed in a separate process 804 after the active layer deposition, so residue and debris from the scribe will not affect the semiconductor layers.

FIG. 9 is a simplified diagram of one example of a factory for implementing an improved process flow according to the present invention.

As shown in FIG. 9, factory 900 includes a tool pair comprising deposition system 902 and a scribe and connect system 904. Deposition system 902 can be implemented by a modified system capable of processing Generation 8 substrates (i.e. 2160 mm×2460 mm class) such as an AKT-40K system provided by AKT, Inc. of Santa Clara, Calif. that has been modified and adapted in accordance with the principles of the invention. For example, while the existing AKT system has a circular central transfer chamber and up to five process chambers, this system has a linear transfer chamber and eight or more process chambers. Each process chamber has an isolation valve at its entry so that it may run at an optimum pressure and gas mixture independent of the other chambers. Chambers are selected to balance the process flow. For example, PVD deposition of Mo is a relatively fast process, so only one chamber is provided (although two may be used to enable maintenance or target changes without stopping the process flow). Assuming one CIGS deposition takes three times longer than one Mo deposition, three CIGS chambers are provided to balance the flow. Additional chambers are provided for each layer. The system has an entry and exit loadlock, and flow of substrates moves from left to right, using one or more transfer robots on tracks in the transfer chamber.

In an example of system 902 for the stack deposition in accordance with certain embodiments of the invention, system 902 includes chambers 906 for respectively depositing the various layers of the stack. As shown in FIG. 9, there are respective chambers for a conductor layer of metal such as molybdenum, semiconductor such as CIGS, and a TCO layer such as ZnO. Chambers for other processes such as an anneal, selenization, and CdS deposition may also be included as necessary. As will be understood by those skilled in the art, the number of chambers for each layer roughly reflects the respective relative time required to deposit the correct thickness of each layer.

Scribe and connect system 904 can be implemented with conventional laser and/or mechanical scribes, polymer application and removal tools, electroless, ink-jet and other types of conductor deposition tools, lamps for photosensitive layer exposure, as adapted in accordance with the embodiments of the invention discussed above.

As shown in FIG. 9, the scriber system 904 and the deposition system 902 are coupled with a linear track 908 that automatically transfers substrates from deposition system 902 to scriber system 904.

Within scriber system 904, it is necessary to scan the scribing and, in some embodiments, the insulator and/or conductor deposition systems with respect to the module substrate. In one embodiment, the module substrate is mounted on a stage and moved. In another embodiment, the substrate is moved in an axis perpendicular to the direction of the scribe lines and the scriber is mounted on a linear drive and moved in an axis parallel to the direction of the scribe lines. In one alternative arrangement, more than one identical linear drives can be employed for the purpose of increasing throughput, for example, in which at least one is used for scribing and at least one is used for deposition To form the scribe cuts and in some layer deposition embodiments (those, for example, using ink jet deposition) it will be necessary to scan the cutting and deposition tool along the substrate. In one example, the laser output is fiber coupled and the end of the fiber is fixed to a linear drive that moves the laser beam along the substrate. In another example, several linear drives run in parallel. In another example, a photosensitive polymer applicator (ink jet, spray or roller) is mounted on the same drive to apply photosensitive polymer after the cut is formed. In another example, the laser beam is fixed, as is the ink jet, spray or roller, and the substrate is moved. In some embodiments, the linear drive refers to a linear motor or lead screw that scans a head containing, for example, a fiber output for the laser and an ink jet along the substrate.

An additional benefit yielded by the present invention is that the interconnect is narrower than possible with the conventional process. The conventional interconnect is 0.05 to 0.1 cm wide; the new process enables the cut interconnect width (the dimension W in FIGS. 6 and 7) to be reduced to 0.01 to 0.2 cm, about 20% of the conventional width. This is in part possible because the insulator 616 removes the parasitic back resistor (and thus blocks the resulting shunt current 1004) through the semiconductor layer 604, as shown in FIG. 10, and in part because the cut is formed in a single process, so that multiple long scribes do not need to be aligned to one another.

Efficiency can be improved in several ways, and the embodiments of the invention can be combined in various ways for various results. For example, the conventional area loss of about 7-10% could be reduced to 1.5-2%. Even greater benefit can be obtained by making the module cells narrower by, for example, a factor of 3. This reduces resistive losses in the TCO and allows use of a thinner TCO. The thicker TCO required for the wider cells may absorb about 10% of the incident light; this can be reduced in the present invention to less than 5%.

A baseline thin-film module has 12.8% efficiency, as is typical of a module made today. However, PSPICE calculations reveal many efficiency improvements gained by the present invention. For example, the smaller width interconnect lines reduce area lost to the interconnect from 8% to 2%, boosting efficiency through an increase in active area. The elimination of the shunt resistor (by improved insulation) boosts efficiency from 12.8% to 15%, even if the interconnect area loss is held at 8%. The individual cells in the module could also be made narrower, reducing the loss in the TCO series resistance. A reduction in cell width by a factor of 3, coupled with the elimination of the shunt resistor, increases efficiency from 12.8% to 17%, making the thin-film module of the present invention very competitive with single crystal modules.

Embodiments of the invention set forth above include an advantage that all the layers of the stack can be deposited in a single process sequence that is uninterrupted by any load and lock transitions. However, this aspect is not necessary for all embodiments of the invention. More particularly, other embodiments of the invention result in greatly improved scribe widths and cell area ratios with associated advantages similar to those described above.

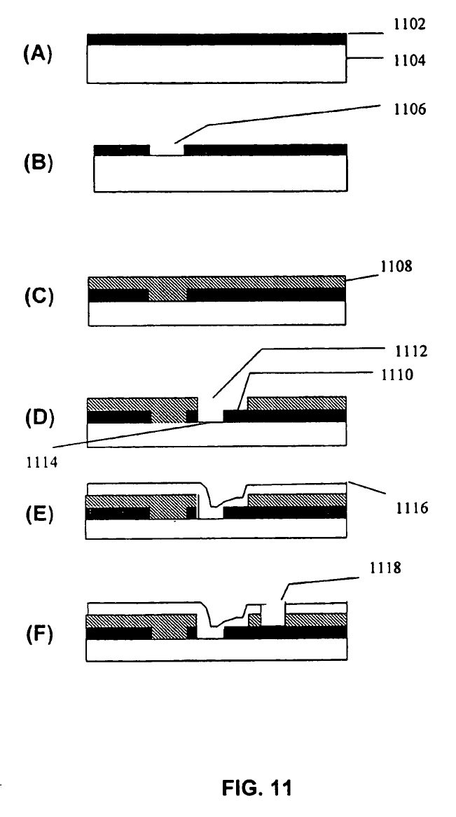

For example, an improved process sequence resulting in an improved thin-film photovoltaic device in accordance with an alternative embodiment of the invention is shown in FIGS. 11A-F. As shown in FIG. 11A, a conductor layer 1102 is first deposited on a substrate such as glass 1104. Next, in FIG. 11B a scribe 1106 is made through the conductor layer 1102. Then in FIG. 11C a semiconductor layer 1108 such as CIGS is deposited. The next step illustrated in FIG. 11D depicts an important and novel step in the process of this embodiment. Specifically, a shaped laser beam is used to make a cut 1112 parallel to scribe 1106 that on one side (the left side in the orientation of the drawing) cuts all the way through the conductor to the underlying insulator, and on the other side cuts only to the conductor layer 1102. This shaped beam forms an isolating groove 1114, as well as a conductive ledge 1110. Optionally, an additional insulator material may also be deposited against the left wall of the cut 1112.

Next in FIG. 11E, top conductor layer 1116 such as TCO is deposited which partially fills the cut 1112 and thereby forms an electrical connection to the conductive ledge 1110. Finally, in FIG. 11F a third scribe 1118 is made parallel to the cut 1112 that cuts through to semiconductor layer 1108 and isolates the cells.

In accordance with aspects of this embodiment of the invention, if cut 1112 is done with a laser (as opposed to a mechanical scribe, as is typical of the prior art), then insulator material ablated from the glass 1104 will deposit on the left wall (in the orientation of the drawing). This will form an insulating residue (not shown), or, at the very least, a residue that will degrade the quality of the contact of the conducting layer 1116 to the sidewall, thereby reducing the reverse shunt leakage. If this leakage is reduced, then the interconnect can be made narrower, as one of the primary reasons of using a wide interconnect is to lengthen the path through which the reverse shunt current must flow to increase the resistance of the path.

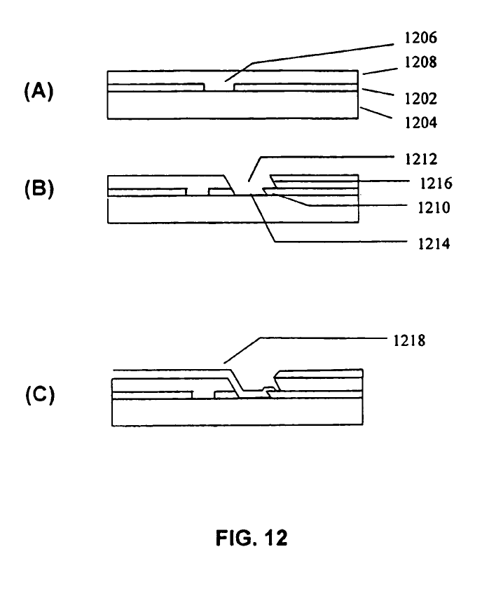

An alternative process to that shown in FIGS. 11A to 11F is shown in FIGS. 12A to 12C. In this embodiment, as shown in FIG. 12A, a conductor layer 1202, scribe 1206 and semiconductor layer 1208 can be formed on substrate 1204 as in the preceding process. Differently, however, in FIG. 12B, scribe 1212 is made parallel to scribe 1206 using a laser beam that is incident at an angle, forming a re-entrant sidewall 1216 in addition to conductive ledge 1210. As in the previous embodiment, no insulator is shown on the left wall of the scribe 1212. However, ablation of insulating substrate 1204 will deposit a coating on this wall. Accordingly, as shown in FIG. 12C, if conductor layer 1218 such as TCO is deposited using a PVD process, for example, it is possible that deposition can be prevented on the re-entrant wall 1216, creating a break in the TCO coverage that eliminates the need for a third scribe, which further improves interconnect width and cell area ratios. In some cases, the sidewall coating is sufficiently resistive, and scribe 1206 is also not required, reducing the interconnect to a single scribe.

It should be noted that an angled cut such as that discussed above could be used in combination with other embodiments to, for example, control the sidewall angle so that is easier to coat with an insulator or insulator plus metal.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A method for forming an interconnect for a thin film solar cell, comprising:
depositing a stack of active and conducting layers of the cell, wherein the depositing step is done in a single process sequence; and
forming the interconnect.

2. The method of claim 1, wherein the forming step includes making more than one cut in the stack, at least one of the cuts being completely through the stack to an underlying insulator.

3. The method of claim 2, wherein the forming step includes making another cut adjacent to the at least one cut that cuts through the active layers and exposes a conducting ledge on the underlying insulator.

4. The method of claim 2, in which a laser is used to make at least one of the cuts.

5. The method of claim 2, wherein a mechanical scribe is used for at least one of the cuts.

6. The method of claim 2 wherein the forming step further includes depositing an insulator followed by depositing a conductor in a region of the cuts.

7. The method of claim 3 wherein the forming step further includes depositing an insulator followed by depositing a conductor in a region of the cuts.

8. The method of claim 1 wherein the forming step includes forming at least one layer of the interconnect using an ink jet process.

9. The method of claim 1 wherein an additional layer is deposited on top of the stack to improve contact resistance of the interconnect.

10. The method of claim 6 wherein the insulator is a photosensitive material.

11. The method of claim 7 wherein the insulator is a photosensitive material.

12. The method of claim 10 wherein the insulator is exposed in a self-aligned manner through a substrate on which the stack is deposited.

13. The method of claim 11 wherein the insulator is exposed in a self-aligned manner through a substrate on which the stack is deposited.

14. The method of claim 1 wherein the process sequence is within vacuum.

15. The method of claim 1 wherein the interconnect forming step includes depositing a conductive layer in a process that is independent of the single process sequence for depositing the active layers.

16. The method of claim 15, wherein the separately deposited conductive layer is opaque.

17. The method of claims 16, wherein the conductive layer is plated onto a photoconductor.

18. The method of claim 1, wherein the forming step includes making a cut through the stack, a first portion of the cut being completely through the stack to an underlying insulator, and a second portion of the cut being through the active layers and forming a conducting ledge on the underlying insulator.

19. A system for forming an interconnect for a thin film solar cell comprising:
a scriber; and
a deposition system,
wherein the deposition system deposits a stack of active and conducting layers of the cell in a single vacuum process.

20. The system of claim 19, wherein elements of the scriber for forming the interconnect comprising an insulator or conductor are mounted on a linear drive.

21. The system of claim 19, further comprising more than one identical linear drives for the purpose of increasing throughput.

22. The system of claim 19, wherein the scriber is stationary and a substrate on which the solar cell and interconnect is formed is moved therethrough.

23. The system of claim 22, wherein the scriber includes one or more scribe and/or deposition heads, and a drive for moving the substrate for processing by the heads.

24. The system of claim 23, wherein the scriber includes one or more scribe and/or deposition heads, and respective drives for moving both the heads and a substrate on which the solar cell and interconnect is formed during processing.

25. The system of claim 19, further comprising more than one linear drive, in which at least one is used for scribing and at least one is used for deposition.

26. The system of claim 19 wherein the scribing system uses a laser.

27. The system of claim 26 wherein an optical fiber carries the laser beam.

28. The system of claim 19 wherein the scribing system uses a mechanical scribe.

29. The system of claim 19 wherein the deposition system uses an ink jet.

30. The system of claim 19 wherein the scriber includes a conductor deposition system that uses plating.

31. The system of claim 19, wherein the scriber forms the interconnect by making one or more cuts in the stack, the one or more cuts including a first portion that is completely through the stack to an underlying insulator and a second adjacent portion that forms a conducting ledge on the underlying insulator.

32. A module of thin-film solar cells, at least one the cells comprising:
a stack on a substrate comprising at least an active layer and a top conducting layer, the cell having a wall abutting all layers of the stack and extending to a surface of the substrate; and
an interconnect to an adjacent one of the cells, the interconnect including:
a conductive ledge on the surface of the substrate that connects to the adjacent cell and is disposed across from the wall along the substrate by a gap; and
a conductor bridging the gap that forms an electrical connection between the top conducting layer of the cell and the conductive ledge.

33. The module of claim 32, wherein the interconnect further includes an insulator between the conductor and at least a portion of the wall that abuts the active layer.

34. The module of claim 32, wherein the stack includes an interface layer deposited on top of the top conducting layer to improve contact resistance of the interconnect.

35. The module of claim 32, wherein the active layer comprises CIGS.

36. The module of claim 32, wherein the active layer comprises amorphous silicon.

37. The module of claim 32, wherein the top conducting layer comprises a TCO.

38. The module of claim 37, wherein the TCO is ZnO.

39. The module of claim 32, wherein the conductive ledge comprises a metal.

40. The module of claim 32, wherein the conductive ledge comprises a TCO.

41. The module of claim 33, wherein the insulator comprises a photosensitive material.

42. The module of claim 34, wherein the interface layer is opaque.

43. The module of claim 32, further comprising a scribe in the top conducting layer that isolates the cell from the adjacent cell.

44. The module of claim 32, further comprising a re-entrant sidewall in the active layer of the adjacent cell proximate to the conductive ledge and defining a second gap between the conductor and the active layer of the adjacent cell.

45. A method for forming an interconnect for a thin film solar cell, comprising:
depositing an active layer on a bottom conducting layer of the cell; and
making a cut through the layers using a shaped laser beam such that a first portion of the cut proceeds through the bottom conducting layer while a second portion of the cut does not but exposes a conducting ledge coupled to an adjacent cell.

46. The method of claim 45, further comprising:
depositing a top conducting layer over the cut layers and the conducting ledge; and
making another cut through the top conducting layer to isolate the cell from the adjacent cell.

47. The method of claim 45, wherein the shaped laser beam is incident at an angle such that a sloped re-entrant sidewall is formed in the active layer above the conducting ledge.

48. The method of claim 47, further comprising:
depositing a top conducting layer over the cut layers and the conducting ledge,
wherein the deposited top conducting layer material is prevented from forming on the re-entrant sidewall.

49. The method of claim 45, wherein the step of making a cut causes ablation of insulator to provide an insulating coating on a sidewall of the cell that abuts at least a portion of the active layer.

50. The method of claim 4, wherein the cut performed by a laser causes ablation of the underlying insulator to provide an insulating coating on a sidewall of the cell that abuts at least a portion of the active layer.

51. The method of claim 18, wherein the cut is performed by a laser and causes ablation of the underlying insulator to provide an insulating coating on a sidewall of the cell that abuts at least a portion of the active layer.
